(19) United States
(12) Patent Application Publication
(10) Pub. No.: US 2009/0135165 A1
(43) Pub. Date: May 28, 2009

(54) CURRENT DRIVER DEVICE

(75) Inventors: Shinichi FUKUZAKO, Kanagawa (JP); Reiji Hattori, Fukuoka (JP)

Correspondence Address: Studebaker & Brackett PC, 1890 Preston White Drive, Suite 105, Reston, VA, 20191, US

(73) Assignee: OKI SEMICONDUCTOR CO., LTD., Tokyo (JP)

(21) Appl. No.: 12/275,667

(22) Filed: Nov. 21, 2008

(30) Foreign Application Priority Data
Nov. 27, 2007 (JP) 2007-305570

(51) Int. Cl. G10L 19/02

(52) U.S. Cl. 345/204

(57) ABSTRACT

The present invention provides a current-driven driver device capable of current writing at high speed even when a parasitic capacitance exists in a circuit to be driven. Each of current driver circuits includes a first current source for supplying a data current of a current value corresponding to a data signal, and a second current source including a differentiation circuit generating a differential value of a voltage applied to each data line and for supplying a boost current of a current value corresponding to the differential value to the data line.

### BACKGROUND OF THE INVENTION

The present invention relates to a driver circuit, and particularly to a driver device for driving a display device such as an active matrix display including light-emitting elements such as an LED (light-emitting diode) and the like.

A display device using an organic light emitting diode (OLED) has been in the limelight as a promising next-generation display. A passive matrix organic light emitting diode (PM-OLED) display has been industrialized and applied in many fields in recent years. There has however been a demand for high performance inclusive of a main display of a cellular phone, etc. In order to find widespread application to various products, there is a need to apply an active matrix organic light emitting diode (AM-OLED) display thereto.

AM-OLEDs are divided according to materials that constitute transistors, i.e., amorphous silicon, low-temperature polysilicon, micro crystal silicon, high-temperature polysilicon, etc. The amorphous silicon and the low-temperature polysilicon are generally used a lot. The amorphous silicon is low in process cost, but has a problem of reliability depending on a threshold voltage shift based on the time of use. On the other hand, the low-temperature polysilicon has a problem about variations in threshold voltage, but is a material that is now being most-frequently adopted.

Driver circuits used in such a display device are grouped roughly into one based on a voltage-driven method and one based on a current-driven method (or voltage program system and current program system). The driver circuit based on the voltage-driven method has an advantage in that LSI is inexpensive and the threshold voltage can be corrected, but involves a process problem that a variation in mobility must be reduced. Due to it, a problem occurs in that yields are reduced.

On the other hand, attention is being given to a current-driven system (e.g., patent document 1 (Japanese Unexamined Patent Publication No. 2005-31430 (paragraphs [0062]-[0067] and FIG. 13)) as a driving method which can correct not only a threshold voltage but also a variation in mobility thereby to solve the problem of a reduction in yield. A problem however arises in that due to the parasitic capacitance of each data line, a write time interval becomes long due to the current in a driver based on the current-driven system. In particular, a problem arises in that the time is taken under the current of a low level.

As described even in the patent document 1, for example, each of electric circuits for respective pixels is generally provided with a control (selection) transistor to which a scan signal is applied, a data voltage holding capacitor and a driving transistor connected to the holding capacitor to perform the driving of each light emitting element or diode. At the control of light emission of the current-driven system, current corresponding to a data signal is caused to flow through the data voltage holding capacitor, and the driving transistor is controlled by the corresponding holding voltage to perform the light-emission control (patent document 1, for example). A problem however arises in that the parasitic capacitance exists in each pixel electric circuit to which a line (data line) for the data signal is connected, and the writing (charging) of data into the holding capacitor become slow due to the parasitic capacitance.

The time allowable for writing at a panel with VGA-class resolution (display resolution of 640×480 size) is about 30 μsec, for example. A problem however arises in that the charging time increases as a current value becomes low, and data cannot be written within the allowable time as the case may be.

In order to cope with such a problem, A. Nathan et al., in Canada have proposed a current-driven system using a current conveyor II (non-patent document 1 (G. R. Chaji and A. Nathan, “A fast setting current driver based on the CCII for AMOLED displays,” IEEE J. of Display Technology, vol. 1, no. 2, pp. 283-288, December 2005)). This method aims to solve a delay developed due to the parasitic capacitance by using feedback. In the present method, the delay can be most reduced when a comparing capacitance CY is set slightly smaller than a parasitic capacitance CP. There is however a demerit that the comparing capacitance is large and the area of a driver increases.

G. H. Cho et al. in Korea have adopted a method of adjusting the amount of supply of current through feedback after a reference current amount has been stored (non-patent document 2 (Young-Suk Son, Sang-Kyung Kim, Yong-Joon Jeon, Young-Jin Woo, Jin-Yong Jeon, Geon-Ho Lee, and Gyu-Hyeong Cho “A Novel Data-Driving method and Circuit for AMOLED Displays” SID 2006 DIGET 2006, 343)). In the present method, a method for reading data according to time sharing and using the data in a base, and a method for reading data at an adjoining line and using the same in the next line, etc. have been adopted. Such methods are also quite complex.

### SUMMARY OF THE INVENTION

The present invention has been made in view of the foregoing pints. It is an object of the present invention to provide a current-driven driver device capable of current writing at high speed even when a parasitic capacitance exists in a circuit to be driven. The present invention aims particularly to provide a driver device capable of current writing at high speed even in the case of a low current.

According to one aspect of the present invention, for attaining the above objects, there is provided a current driver device comprising at least one current driver circuit for supplying a data current to each of data lines, based on a data signal, wherein each of the current driver circuits includes a first current source for supplying a data current having a current value corresponding to the data signal, and a second current source including a differentiation circuit generating a differential value of a voltage applied to the data line, and for supplying a boost current of a current value corresponding to the differential value to the data line.

The driver circuit of the present invention has a second current source including a differentiation circuit used to generate a differential value of a voltage applied to each data line, and for supplying a boost current of a current value corresponding to the differential value to the data line in addition to a first current source for supplying a data current having a current value corresponding to a data signal.

That is, there is provided a second current source for compensating for charging by a parasitic capacitance even when the parasitic capacitance exists in each data line (circuit to be driven). Accordingly, the charging by the parasitic capacitance is canceled out, and a pixel circuit or the like of a display device, which is connected to each data line, can be charged at high speed. Incidentally, the second current source operates as a negative capacitance with respect to the parasitic capacitance.

### BRIEF DESCRIPTION OF THE DRAWINGS

While the specification concludes with claims particularly pointing out and distinctly claiming the subject matter which is regarded as the invention, it is believed that the invention, the objects and features of the invention and further objects, features and advantages thereof will be better understood from the following description taken in connection with the accompanying drawings in which:

FIG. 1 typically shows a display device as one example of a device in which a data driver illustrative of a first preferred embodiment of the present invention is used;

FIG. 2 is a block diagram typically showing equivalent circuits of the data driver (driver device) illustrative of the first preferred embodiment and a pixel circuit of a pixel PXᵢⱼ;

FIG. 3 is a block diagram showing one example of a current boost circuit according to the present embodiment;

FIG. 4 is a diagram typically showing a voltage V (FIG. 4(a)) of a pixel circuit where a boost current Ibs is zero (Ibs=0), and its differential operation curve (FIG. 4(b)) respectively;

FIG. 5 is a diagram illustrating an equivalent circuit of a differentiation circuit comprising a resistor R0 and a capacitor C0;

FIG. 6 is a diagram typically showing a generated boost current Ibs (FIG. 6(a)) and a voltage (charging voltage of holding capacitor) V of a pixel circuit where a current Id (=Idata+Ibs) is supplied to the pixel circuit as a data current;

FIG. 7 is a circuit diagram illustrating one example of a concrete circuit of the current boost circuit; and

FIG. 8 is a circuit diagram showing one example of a concrete circuit of a current boost circuit illustrative of a second preferred embodiment of the present invention.

### DETAILED DESCRIPTION OF THE PREFERRED EMBODIMENTS

Preferred embodiments of the present invention will hereinafter be described in detail with reference to the accompanying drawings. Incidentally, the same reference numerals are respectively attached to constituent elements and portions substantially identical or equivalent in the drawings described below.

### First Preferred Embodiment

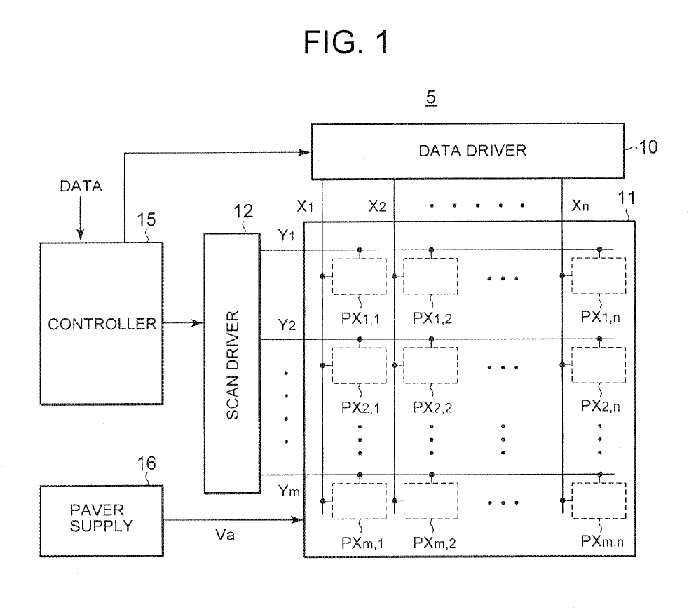

A driver device (data driver) according to the present invention will be explained below. FIG. 1 typically shows a display device 5 as one example of a device in which a data driver 10 illustrative of a first preferred embodiment of the present invention is used.

The display device 5 is provided with the data driver 10, a display panel 11, a scan driver 12, a controller 15 and a light-emitting element driving power source PS (hereinafter also called simply “power source PS”) 16.

The display panel 11 is of an active matrix type display panel comprised of pixels of m rows and n columns (m×n: m and n being integers greater than or equal to 1). The display panel 11 has a plurality of scan lines Y1 through Ym (where Yi: i=1 through m) respectively disposed in parallel, a plurality of data lines X1 through Xn (Xj: j=1 through n) respectively orthogonal to the scan lines, and a plurality of pixels PX_{1,1} through PX_{m,n}. The pixels PX_{1,1} through PX_{m,n} are respectively disposed at portions where the scan lines Y1 through Ym and the data lines X1 through Xn intersect, and are all identical in configuration. The pixels PX_{1,1} through PX_{m,n} are connected to a source line (not shown). A light-emitting element drive voltage (Va) is supplied from the power source PS 16 to the light emitting elements in the respective pixels through the power line.

Circuits (hereinafter also called “picture element circuits or pixel circuits PX_{i,j}) of the respective pixels PX_{i,j} are connected to the scan lines Yi and the data lines Xj. Each of the pixel circuits PX_{i,j} has a selection transistor, a data holding capacitor, a drive transistor and a light emitting element (e.g., organic electroluminescent light-emitting element or diode (OEL)). Each of the selection transistor and the drive transistor is formed by, for example, a thin film transistor (TFT)).

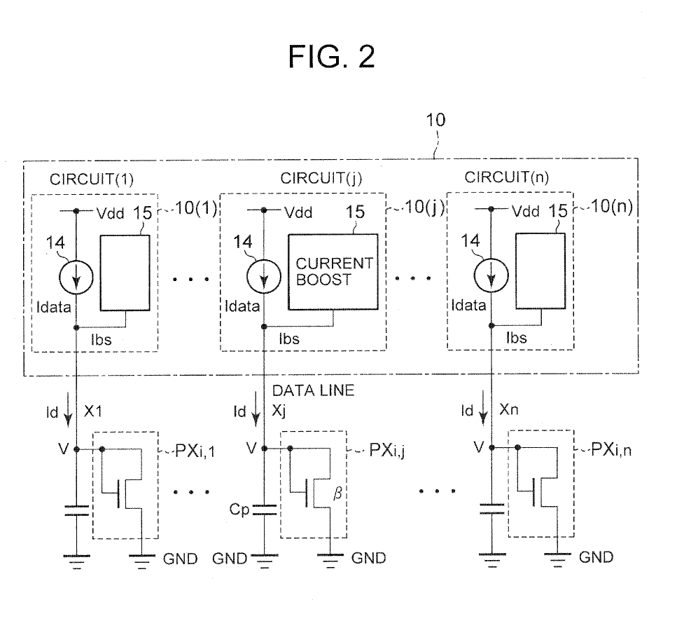

FIG. 2 is a block diagram typically showing equivalent circuits of the data driver (driver device) 10 according to the first preferred embodiment and the pixel circuits of the pixels PX_{i,j} (where j=1, . . . , j, . . . , n). Incidentally, symbols PX_{i,j} are used below even for the pixel circuits of the pixels PX_{i,j} for convenience of explanation and represented as the pixel circuits PX_{i,j}.

The data driver 10 has a circuit configuration adapted to a current-driven system (current program system). Described more specifically, the data driver 10 has data current output ends respectively connected to the data lines X1 through Xn of the display panel 11. The data current output ends are connected to their corresponding data lines X1 through Xn. The data driver 10 has driver circuits (current driver circuits) 10(1), . . . , 10(j), 10(n) which supply data currents to the data line Xj (where j=1, . . . , n) respectively. The driver circuit 10(j) and the pixel circuit PX_{i,j} connected to the driver circuit 10(j) will generally be explained below.

Incidentally, the data driver 10 supplies data currents in response to a control signal, a data signal and the like sent from an external circuit (e.g., controller 15).

The driver circuit 10(j) is provided with a current source 14 (first current source) for supplying a data current Idata to its corresponding data line Xj. That is, the current source 14 generates a constant current (data current) Idata corresponding to a data signal (data value) and supplies the same to the corresponding data line Xj.

In the present embodiment, a current boost circuit 15 is further provided in addition to the current source 14 (first current source). The current boost circuit 15 (second current source) generates a boost current Ibs and supplies the same to the data line Xj. Namely, the current obtained by adding the boost current Ibs to the data current Idata is supplied to the data line Xj. The configuration and operation of the current boost circuit 15 and the boost current Ibs will be described in detail later. Incidentally, such a configuration is similar even to the driver circuits 10(j) (where j=1, . . . , n) as described above.

Upon writing of data into each pixel (pixel circuit), the data current Idata is generated by the current source 14 and supplied to the data line Xj. As shown in the equivalent circuits of FIG. 2, parasitic capacitances (Cp) exist in the respective pixel circuits PX_{i,j}. Thus, assuming that the voltage of each pixel circuit (data line Xj) is V, the following current flows through the parasitic capacitance (Cp) of the pixel circuit.

$$Ip = Cp \frac{d V}{d t} \qquad ( 1 )$$

Therefore, the writing of data into each pixel circuit (charging of data holding capacitor) becomes slow. Namely, part of the data current Idata from the current source 14 is consumed or used up to charge the parasitic capacitance Cp.

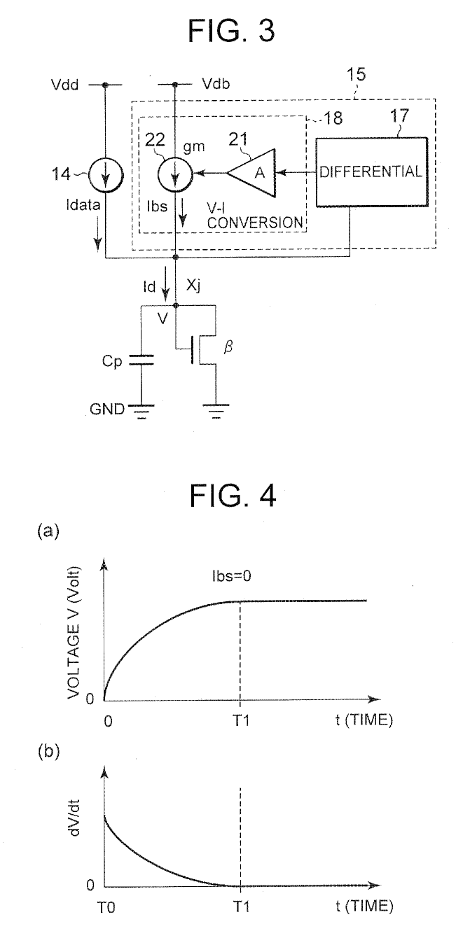

FIG. 3 is a block diagram showing one example of the current boost circuit 15 according to the present embodiment. The configuration of the current boost circuit 15 and the principle and outline of its boost operation will be explained with reference to the drawings to begin with. In the present embodiment, the current boost circuit (hereinafter also called simply “boost circuit”) 15 comprises a differentiation circuit 17 and a V-I conversion circuit 18. The differentiation circuit 17 performs a differentiation operation (K·dV/dt, and K: constant) of the voltage V of the pixel circuit.

FIGS. 4(a) and 4(b) are diagrams respectively typically showing a voltage V of each pixel circuit where a boost current Ibs is zero (Ibs=0), and its differential operation curve. Described specifically, the voltage V of the pixel circuit gradually increases with the supply of a data current Id (=Idata+Ibs=Idata). After a time T1 has elapsed since the start time (t=0) of supply of the data current Id, data writing is completed. When the boost current Ibs is zero (Ibs=0) as described above, the charging of a data holding capacitor becomes slow due to the charging into the parasitic capacitance (Cp) of the pixel circuit.

The V-I conversion circuit 18 comprises, for example, an amplifier 21 and a variable current source 22. The V-I conversion circuit 18 generates a boost current Ibs corresponding to the result of differential operation (dV/dt) (proportional to, for example, the result (dV/dt) of differential operation) and outputs the same therefrom.

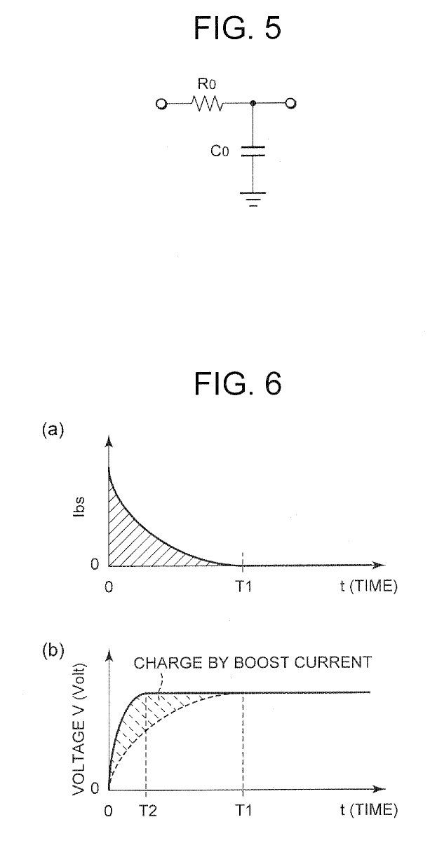

When the differentiation circuit 17 is represented in the form of an equivalent circuit (shown in FIG. 5) comprised of a resistor R0 and a capacitor C0, for example, K=C0−R0. If Cn is set as expressed in the following equation as a negative capacitance (Cn) where the gain of the amplifier 21 is A and the mutual conductance of the current source 22 is gm, then the parasitic capacitance (Cp) of the pixel circuit can be canceled out (that is, Cp+Cn=0).

Cn=−Cp=−(C0−R0)·A·gm (2)

Namely, the boost circuit 15 operates as a circuit equivalent to the negative capacitance (Cn=−Cp). That is, in the data driver 10, the parasitic capacitance of each pixel of the display panel to which the data driver 10 is connected, is set as a predetermined capacitance value, and a circuit configuration may be formed in such a manner that the boost circuit operates as a negative capacitance with respect to the predetermined capacitance value.

To cite concrete numerical examples, the negative capacitance becomes Cn=−10 pF assuming that C0=0.2 pF, R0=1 kΩ, gm=−2×10⁻³ and A=−25 when the parasitic capacitance of the pixel circuit is Cp=10 pF, and hence the parasitic capacitance (Cp) of the pixel circuit is canceled out.

FIG. 6(a) typically shows the boost current Ibs generated in the above described manner, and FIG. 6(b) typically shows a voltage (charging voltage of holding capacitor) V of each pixel circuit where the current Id (=Idata+Ibs) obtained by adding the boost current Ibs to the data current Idata is supplied to the pixel circuit as a data current. A write (charging) current is intensified by charging (hatched portion in the drawing) based on the boost current Ibs, and the writing of data into the pixel circuit is speeded up. That is, it is understood that the charging based on the parasitic capacitance (Cp) is canceled out by compensation based on the boost current Ibs, and the corresponding holding capacitor can be charged at high speed (charging time T2<T1).

It is thus possible to provide a current-driven driver device capable of current writing at high speed without being susceptible to the parasitic capacitance of each pixel circuit (driven circuit).

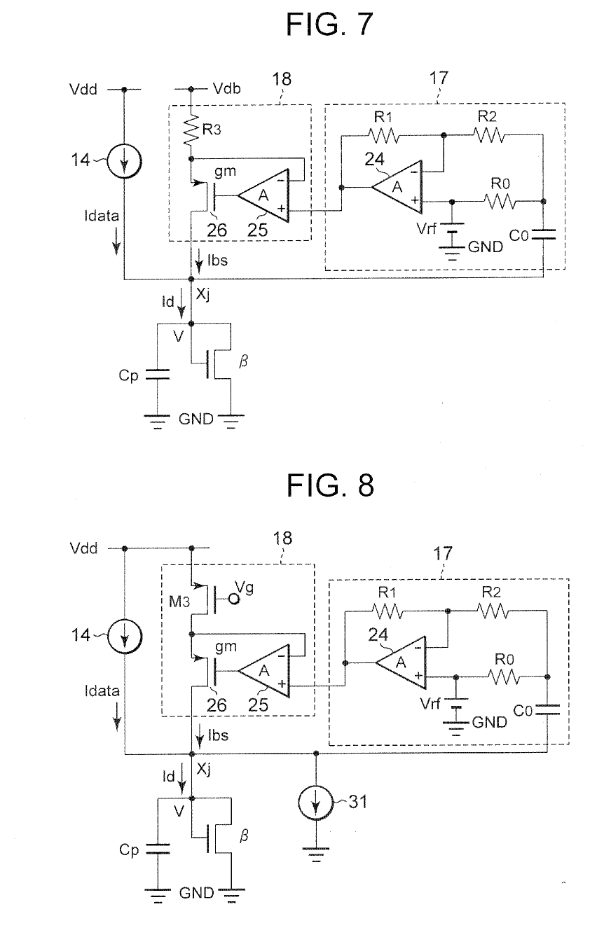

FIG. 7 is a circuit diagram showing one example of a concrete circuit of the current boost circuit 15. A differentiation circuit 17 comprises resistors R0, R1 and R2, a capacitor C0 and a differential amplifier 24. The V-I conversion circuit 18 comprises a resistor R3, a transistor 26 and a differential amplifier 25.

If, in this case, the gain of the differential amplifier 25 is A, the mutual conductance of the V-I conversion circuit 18 is gm and the negative capacitance is set as expressed in the following equation as Cn,

$$\begin{matrix}Cn = - Cp = - ( C 0 \cdot R 0 ) \cdot A \cdot gm \\ = - ( C 0 \cdot R 0 ) \cdot ( R 0 / R 1 ) \cdot ( 1 / R 3 ) \\ = - C 0 ( R 0 \cdot R 1 ) / ( R 2 \cdot R 3 ) ,\end{matrix}$$

then the parasitic capacitance (Cp) of the pixel circuit can be canceled out by the negative capacitance Cn (=−Cp).

It is thus possible to provide a current-driven driver device capable of current writing at high speed without being susceptible to the parasitic capacitance.

Incidentally, the resistor R3 of the V-I conversion circuit 18 is connected to Vdb=Vrf (reference voltage of differential amplifier 24) in the present embodiment. When the resistor R3 is connected to Vdd (source voltage of first current source), for example, a bias current=R3/(Vdd−Vrf) flows. Thus, in this case, a sink circuit for removing the bias current from the output of the V-I conversion circuit 18, i.e., a constant current sink circuit for allowing the bias current to flow into a ground level (GND) may be provided.

Further, when the differential amplifier (op amp) 24 has an offset voltage, a bias current occurs even when the resistor R3 is connected to Vdb=Vrf (reference voltage of differential amplifier 24). In this case, the resistor R3 is connected to a voltage made different by the offset voltage from Vrf thereby to make it possible to prevent the bias current.

### Second Preferred Embodiment

FIG. 8 is a circuit diagram showing one example of a concrete circuit of a current boost circuit 15 illustrative of a second preferred embodiment of the present invention.

In the V-I conversion circuit 18 employed in the first preferred embodiment, the resistor R3 connected in series to the transistor 26 operated as the variable current source is substituted with a transistor M3, thereby making it possible to control a boost current value with a high degree of accuracy. That is, a gate voltage Vg of the transistor M3 connected in series to the transistor 26 is changed on an analog basis thereby to enable its resistance value to vary effectively instead of the resistor R3. It is however necessary to operate the transistor M3 in a linear region.

Incidentally, there is provided a constant current sink circuit 31 which causes a bias current produced in the current boost circuit 15 to flow into a ground (GND) line.

Alternatively, a plurality of transistors different in channel width W are further prepared to cover a broad range of resistance values as another modified example of the present embodiment. For example, a method may be used which uses a plurality of transistors whose channel widths are weighted like W=1, 2, 4 and 8, and controls the conduction of the respective transistors on a digital basis. That is, a plurality of transistors different in current supply capacity are used and combined thereby to make it possible to control a boost current value extensively and with a high degree of accuracy.

There is provided a further modified example which has an advantage in that the differential amplifier (inversion amplifying op amp) 24 is substituted with a grounded-source amplifier circuit thereby to enable a reduction in area.

While the preferred forms of the present invention have been described, it is to be understood that modifications will be apparent to those skilled in the art without departing from the spirit of the invention. The scope of the invention is to be determined solely by the following claims.

What is claimed is:

1. A current driver device comprising:
at least one current driver circuit for supplying a data current to each of data lines, based on a data signal,
wherein each of the current driver circuits includes a first current source for supplying a data current having a current value corresponding to the data signal, and a second current source including a differentiation circuit for generating a differential value of a voltage applied to the data line, said second current source supplying a boost current of a current value corresponding to the differential value to the data line.

2. The current driver device according to claim 1, wherein the second current source is a circuit equivalent to a negative capacitance with respect to a capacitance value of a circuit to be driven.

3. The current driver device according to claim 1, wherein the second current source further has an amplifier for amplifying the differential value and supplies a boost current of a current value corresponding to the amplified differential value to the data line.

4. The current driver device according to claim 1, further including a sink circuit for eliminating a bias current of the second current source.

5. The current driver device according to claim 1, wherein the second current source includes a variable current source and a transistor connected in series to the variable current source and controls the boost current according to a control voltage of the transistor.
